(19) United States
(12) Patent Application Publication
(10) Pub. No.: US 2012/0298953 A1
(43) Pub. Date: Nov. 29, 2012

(54) LIGHT EMITTING DEVICE

(76) Inventor: Se Hwan SIM, Seoul (KR)

(21) Appl. No.: 13/450,078

(22) Filed: Apr. 18, 2012

(30) Foreign Application Priority Data
May 24, 2011 (KR) 10-2011-0048980

(51) Int. Cl. H01L 33/06

(52) U.S. Cl. 257/13; 257/E33.008

(57) ABSTRACT

A light emitting device according to the embodiment includes a substrate having first and second surfaces opposite to each other and formed on the first surface thereof with a plurality of convex parts; and a light emitting structure formed on the first surface of the substrate and including a first conductive semiconductor layer, a second conductive semiconductor layer, and an active layer between the first and second conductive semiconductor layers. The light emitting structure has holes corresponding to the convex parts of the substrate.

### BACKGROUND

Light emitting diodes (LEDs) are semiconductor devices that convert electric energy into light. The LED is advantageous as compared with conventional light sources, such as a fluorescent lamp or a glow lamp, in terms of power consumption, life span, response speed, safety and environmental-friendly requirement.

In this regard, various studies have been performed to replace the conventional light sources with the LEDs. The LEDs are increasingly used as light sources for lighting devices such as various lamps, liquid crystal displays, electric signboards, and street lamps.

### SUMMARY

The embodiment provides a light emitting device capable of improving the efficiency and reliability.

A light emitting device according to the embodiment includes a substrate having first and second surfaces opposite to each other and formed on the first surface thereof with a plurality of convex parts; and a light emitting structure formed on the first surface of the substrate and including a first conductive semiconductor layer, a second conductive semiconductor layer, and an active layer between the first and second conductive semiconductor layers. The light emitting structure has holes corresponding to the convex parts of the substrate.

According to the embodiment, the light extraction efficiency can be improved by using the substrate having the convex parts. In addition, holes are formed corresponding to the convex parts, so that the defect can be prevented in the vicinity of the convex parts and the light extraction efficiency can be more improved due to the refraction induced by the holes. Thus, the reliability and the efficiency of the light emitting device can be improved.

In addition, since the semiconductor layer is grown in a state that the holes have been formed, an additional process to form the holes may not be necessary and the light emitting structure can be prevented from being damaged.

### BRIEF DESCRIPTION OF THE DRAWINGS

FIG. 1 is a sectional view of a light emitting device according to one embodiment;

FIG. 2 is a perspective view showing a substrate having convex parts and the position of holes in a light emitting device according to one embodiment;

FIG. 3 is a sectional view of a light emitting device according to a modified example;

FIG. 4 is a sectional view of a light emitting device according to another modified example;

FIG. 5 is a perspective view showing a substrate having convex parts and the position of holes in a light emitting device according to another modified example;

FIGS. 6 to 8 are sectional views showing a method of fabricating a light emitting device shown in FIG. 1;

FIG. 9 is a photographic view showing a section of a semiconductor layer which is grown to have holes corresponding to convex parts of a substrate;

FIG. 10 is a photographic view showing a top surface of a semiconductor layer which is grown to have holes corresponding to convex parts of a substrate;

FIG. 11 is a photographic view showing a top surface of a buffer layer which is grown to have holes corresponding to convex parts of a substrate;

FIG. 12 is a graph showing a voltage, which is measured by aging light emitting devices according to manufacture examples using a current of 80 mA;

FIG. 13 is a graph showing a voltage, which is measured by aging light emitting devices according to manufacture examples using a current of 10 μA;

FIG. 14 is a graph showing a voltage, which is measured by aging light emitting devices according to manufacture examples using a current of 1 μA;

FIG. 15 is a graph showing a voltage, which is measured by aging light emitting devices according to manufacture examples using a current of 0.1 μA;

FIG. 16 is a graph showing a voltage, which is measured by aging light emitting devices according to manufacture examples using a voltage of −5V;

FIGS. 17 to 24 are sectional views showing the procedure for fabricating a light emitting device according to another embodiment;

FIG. 25 is a sectional view of a light emitting device package including a light emitting device according to the embodiment;

FIG. 26 is an exploded perspective view showing a backlight unit including a light emitting device package according to the embodiment; and

FIG. 27 is a perspective view showing a lighting unit including a light emitting device package according to the embodiment.

### DETAILED DESCRIPTION OF THE EMBODIMENTS

In the description of the embodiments, it will be understood that, when a layer (film), a region, a pattern or a structure is referred to as being “on” or “under” another layer (film), another region, another pattern, or another structure, it can be “directly” or “indirectly” on the other layer (film), region, pattern or structure, or one or more intervening layers may also be present. Such a position of the layer has been described with reference to the drawings. The size of elements shown in the drawings may be exaggerated for the purpose of convenience or clarity. In addition, the size of elements does not utterly reflect an actual size. Hereinafter, embodiments will be described in detail with reference to accompanying drawings.

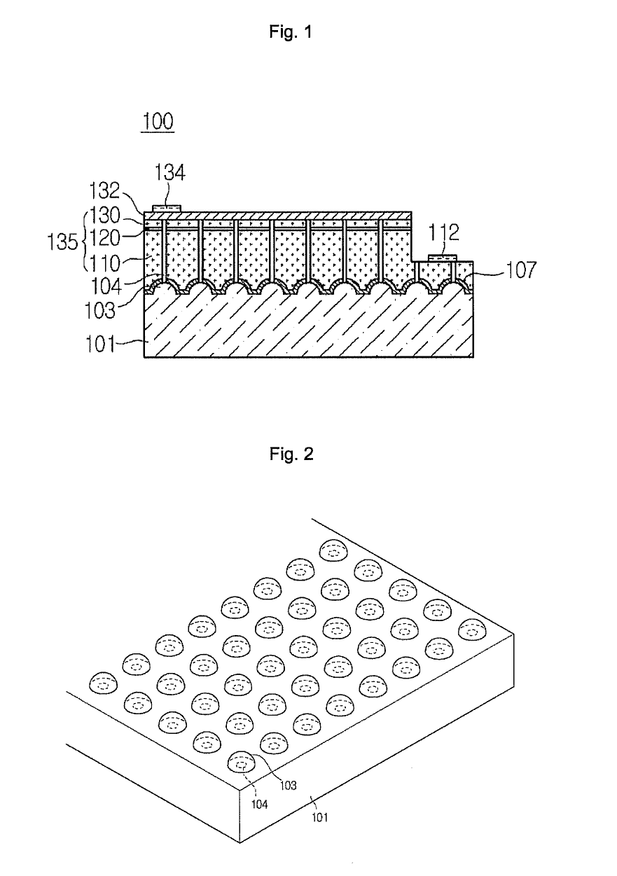

FIG. 1 is a sectional view of a light emitting device according to one embodiment.

Referring to FIG. 1, the light emitting device 100 according to one embodiment includes a substrate 101 formed on a first surface thereof (hereinafter, referred to as top surface) with a plurality of convex parts 103, and a light emitting structure 135 formed on the top surface of the substrate 101 and including a first conductive semiconductor layer 110, an active layer 120 and a second conductive semiconductor layer 130. In addition, a first electrode 112 is provided on the first conductive semiconductor layer 110, and a transmissive conductive layer 132 and a second electrode 134 are formed on the second conductive semiconductor layer 130. Holes 104 are formed in the light emitting structure 135 corresponding to the convex parts 103. The above structure will be described below in more detail.

The substrate 101 may serve as a growth substrate for growing a buffer layer 107 and/or semiconductor layers constituting the light emitting structure 135. Since the convex parts 103 are formed on the top surface of the substrate 101, light travelling in the horizontal direction may be extracted in the vertical direction, so that the light extraction efficiency can be improved. The substrate 101 may include at least one of Al2O3, Si, SiC, GaAs, GaN, ZnO, MgO, GaP, InP and Ge. For instance, a patterned sapphire substrate (PSS) can be used as the substrate 101 having the convex parts 103. However, the embodiment is not limited to the above, but various materials can be used for the substrate 101.

The buffer layer 107 including a semiconductor can be formed on the top surface of the substrate 101. The buffer layer 107 may attenuate the lattice mismatch between the substrate 101 and the light emitting structure 135. The buffer layer may have at least one of AlInN/GaN stack structure, InxGa1−xN/GaN stack structure and InxAlyGa1−x−yN/InxGa1−xN/GaN stack structure, wherein 0≦x≦1, 0≦y≦1, 0≦x+y≦1. In addition, the buffer layer 107 can be formed as a single layer including AlN.

Further, the buffer layer 107 may include an undoped semiconductor layer. Although the undoped semiconductor layer may not be intentionally doped with dopants, the undoped semiconductor layer may be a first conductive nitride layer identical to the first conductive semiconductor layer 110 formed on the undoped semiconductor layer. For instance, the undoped semiconductor layer may include a GaN semiconductor layer.

The light emitting structure 135 formed on the buffer layer 107 may include a plurality of compound semiconductor layers consisting of group III-V elements. The first conductive semiconductor layer 110 is formed on the buffer layer, the active layer 120 is formed on the first conductive semiconductor layer 110, and the second conductive semiconductor layer 130 is formed on the active layer 120.

The first conductive semiconductor layer 110 may include compound semiconductors consisting of group III-V elements doped with first conductive dopant. For instance, the first conductive semiconductor layer 110 may include an n type semiconductor layer. The n type semiconductor layer can be formed by doping the semiconductor material having a compositional formula of InxAlyGa1−x−yN (0≦x≦1, 0≦y≦1, 0≦x+y≦1) with the n type dopant. For instance, the n type semiconductor layer can be formed by doping GaN, AlN, AlGaN, InGaN, InN, InAlGaN, AlInN, AlGaAs, GaP, GaAs, GaAsP or AlGaInP with the n type dopant, such as Si, Ge, Sn, Se or Te. The first conductive semiconductor layer 110 can be prepared as a single layer or a multi-layer, but the embodiment is not limited thereto.

The active layer 120 may have one of a single quantum well structure, a multi quantum well (MQW) structure, a quantum dot structure and a quantum wire structure, but the embodiment is not limited thereto.

The active layer 120 can be formed by using the semiconductor material having a compositional formula of InxAlyGa1−x−yN (0≦x≦1, 0≦y≦1, 0≦x+y≦1). If the active layer 120 has the MQW structure, the active layer 120 may have a stack structure of a plurality of well layers and a plurality of barrier layers. For example, the well/barrier layers of the active layer 120 may include at least one of InGaN/GaN pair structure, InGaN/InGaN pair structure, GaN/AlGaN pair structure, InAlGaN/GaN pair structure, GaAs (InGaAs)/AlGaAs pair structure, and GaP (InGaP)/AlGaP pair structure, but the embodiment is not limited thereto. The well layer may include a material having a bandgap lower than that of a material for the barrier layer.

A clad layer (not shown) doped with an n type dopant or a p type dopant may be formed on and/or under the active layer. The clad layer may include AlGaN layer or an InAlGaN layer.

The second conductive semiconductor layer 130 may include compound semiconductors consisting of group III-V elements doped with second conductive dopant. For instance, the second conductive semiconductor layer 130 may include a p type semiconductor layer. The p type semiconductor layer can be formed by doping the semiconductor material having a compositional formula of InxAlyGa1−x−yN (0≦x≦1, 0≦y≦1, 0≦x+y≦1) with the p type dopant. For instance, the p type semiconductor layer can be formed by doping GaN, AlN, AlGaN, InGaN, InN, InAlGaN, AlInN, AlGaAs, GaP, GaAs, GaAsP or AlGaInP with the p type dopant, such as Mg, Zn, Ca, Sr or Br. The second conductive semiconductor layer 130 can be prepared as a single layer or a multi-layer, but the embodiment is not limited thereto.

Although it has been described that the first conductive semiconductor layer 110 includes the n type semiconductor layer and the second conductive semiconductor layer 130 includes the p type semiconductor layer, the embodiment is not limited thereto. For instance, the first conductive semiconductor layer 110 may include the p type semiconductor layer and the second conductive semiconductor layer 130 may include the n type semiconductor layer. In addition, another n type or p type semiconductor layer (not shown) may be formed under the second conductive semiconductor layer 130. Accordingly, the light emitting structure 135 may have at least one of NP, PN, NPN, and PNP junction structures. In addition, the doping concentration of dopant in the first and second conductive semiconductor layers 110 and 130 may be uniform or non-uniform. In other words, the light emitting structure 135 may be variously modified, and the embodiment is not limited thereto.

The transmissive conductive layer 132 is formed on the second conductive semiconductor layer 130. For instance, the transmissive conductive layer 132 may include at least one of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), ZnO, RuOx, TiOx, and IrOx. The first electrode 112 is formed on the first conductive semiconductor layer 110 at the region where the active layer 120 and the second conductive semiconductor layer 130 have been removed. In addition, the second electrode 134 is formed on the transmissive conductive layer 132.

The first electrode 112 and/or the second electrode 134 may include a metal having superior conductivity. For instance, the first electrode 112 and/or the second electrode 134 may include at least one of Au, Pd, Pt, Ru, Re, Mg, Zn, Hf, Ta, Rh, Ir, W, Ti, Ag, Cr, Mo, Nb, Al, Ni, Cu, WTi, V and an alloy thereof.

For instance, the first electrode 112 and/or the second electrode 134 may include an ohmic layer adjacent to the light emitting structure 135 to make ohmic-contact with the light emitting structure 135 and an electrode layer formed on the ohmic layer. The ohmic layer may include Cr, Al, V or Ti. The electrode layer can be formed by sequentially laminating a barrier layer including Ni or Al, a metal layer including Cu, a barrier layer including Ni or Al and a wire bonding layer including Au, but the embodiment is not limited thereto. The electrode layer can be prepared as a single layer, such as a W layer, a WTi layer, a Ti layer, an Al layer or an Ag layer.

The holes 104 are formed in the light emitting structure 135 according to the embodiment. The holes 104 make contact with the convex parts 103 and extend to the top surface of the light emitting structure 135 (that is, a surface where the transmissive conductive layer 132 is formed) from the convex parts 103. Therefore, as described above, if the buffer layer 107 is formed between the substrate 101 and the light emitting structure 135, the holes 104 are also formed in the buffer layer 107. In addition, a lateral side of the hole 104 is inclined at an angle of 80° to 100° with respect to a second surface (hereinafter, referred to as bottom surface) of the substrate 101, so that the surface area (or width) of the holes 104 may be uniformly formed.

The above structure may be resulted because the semiconductor layers constituting the buffer layer 107 and the light emitting structure 135 are grown on the substrate 101 in a state that the holes 104 are formed in the substrate 101. The growing process will be described later in detail with reference to FIG. 6.

The holes 104 are formed in the light emitting structure 135 corresponding to the convex parts 103. If the substrate 101 formed with the convex parts 103 is employed, the light extraction efficiency can be improved due to the convex parts 103. However, when the buffer layer 107 and/or the light emitting structure 135 is grown on the convex parts 103, many defects may occur on the upper portions of the convex parts 103 due to the problem of crystalline property. These defects may deteriorate the low-current characteristic, so the reliability may be degraded. Thus, according to the embodiment, each hole 104 is formed at the center of each convex part 103 to prevent the above defects. Therefore, the low-current characteristic may not be deteriorated, so the reliability may be improved.

Meanwhile, the semiconductor layers are grown in such a manner that the semiconductor layers may not be grown at the regions corresponding to the holes 104, so the semiconductor layers may have the holes. Thus, an additional process to form the holes 104 may not be necessary. In contrast, if the holes 104 are formed through the etching process, the buffer layer 107 and/or the light emitting structure 135 may be damaged during the etching process.

In addition, since the sectional areas of the holes 104 are gradually reduced toward the convex parts 103, in order to form the holes 104 at upper end portions of the convex parts 103, the etching process must be performed such that an upper end portion of the light emitting structure 135 has a large area. In this case, an area of the light emitting structure 135, which substantially generates the light, can be reduced.

In addition, since the light emitting structure 135 has the holes 104 spaced apart from each other at the regular interval, the light extraction efficiency can be improved. In detail, the holes 104 may have the refractive index lower than that of the buffer layer 107 and/or the light emitting structure 135 because air is provided in the holes 104, so the light generated from the light emitting structure 135 can be refracted through the holes 104. Thus, the light can be effectively extracted in the vertical direction. That is, the light extraction efficiency can be improved by the convex parts 103 and the holes 104.

Hereinafter, the position of the convex parts 103 and holes 104 will be described in more detail with reference to FIGS. 1 and 2. FIG. 2 is a schematic perspective view showing the substrate 101 having the convex parts 103 and the position of the holes 104.

Referring to FIG. 2, when viewed from the top, the holes 104 are positioned at the center portions of the convex parts 103, respectively. That is, the semiconductor layers constituting the buffer layer 107 and the light emitting structure 135 are grown from the peripheral portion of the convex part 103 and are not grown at the center portions of the convex parts 103, so that the holes 104 are positioned at the center portions of the convex parts 103.

An area of each hole 104 may correspond to 5% to 50% based on an area of each convex part 103. If the area of each hole 104 exceeds 50% based on the area of each convex part 103, the size of the hole 104 is excessive, so the stability of the light emitting structure 135 may be degraded and the area contributing to the light may be reduced. In contrast, if the area of the each hole 104 is less than 5% based on the area of each convex part 103, the size of the hole 103 is too small, so the hole 104 may be buried when the semiconductor layers are grown and the defect reduction effect may be diminished. For instance, the area of each hole 104 based on the area of each convex part 103 is about 10% to about 30%.

In order to prevent the holes 104 from being buried when the semiconductor layers are grown, the holes 104 must have the width of at least 0.1 μm. In detail, if the hole 104 has a hexagonal shape, a diagonal line of the hole 104 must have the length of at least at least 0.1 μm. If the hole 104 has a circular shape, the hole 104 must have the diameter of at least at least 0.1 μm. In addition, if the hole 104 has a linear shape, the hole 104 must have the line width of at least at least 0.1 μm.

When taking into consideration the light extraction efficiency and the stability in the growth process, the hole 104 may have the width of at least 0.2 μm to 0.3 μm. However, the embodiment may not be limited to the above, and various modifications are possible.

As described above, since the holes 104 are formed by using the convex parts 103 when the semiconductor layers are grown, the holes 104 may correspond to the convex parts 103 in one-to-one correspondence. When viewed from the top, the holes 104 may have various shapes. For instance, the holes 104 may have the circular shape or the hexagonal shape.

Referring to FIG. 2, the convex parts 103 have the hemispherical structure and the semi-circular sectional shape, but the embodiment is not limited thereto.

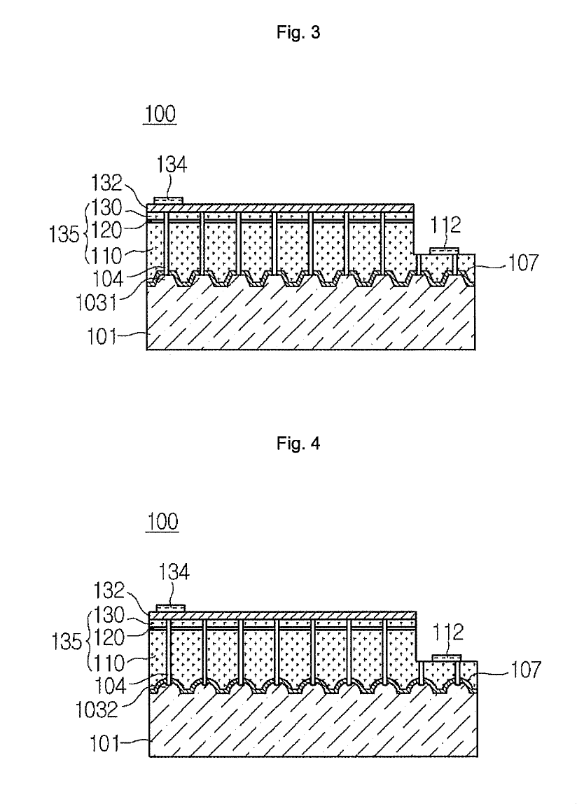

Thus, as shown in FIG. 3, convex parts 1031 may have the polygonal shapes, such as trapezoidal shapes. In addition, as shown in FIG. 4, concave parts can be formed at upper portions of convex parts 1032 and the holes 104 are positioned in the concave parts.

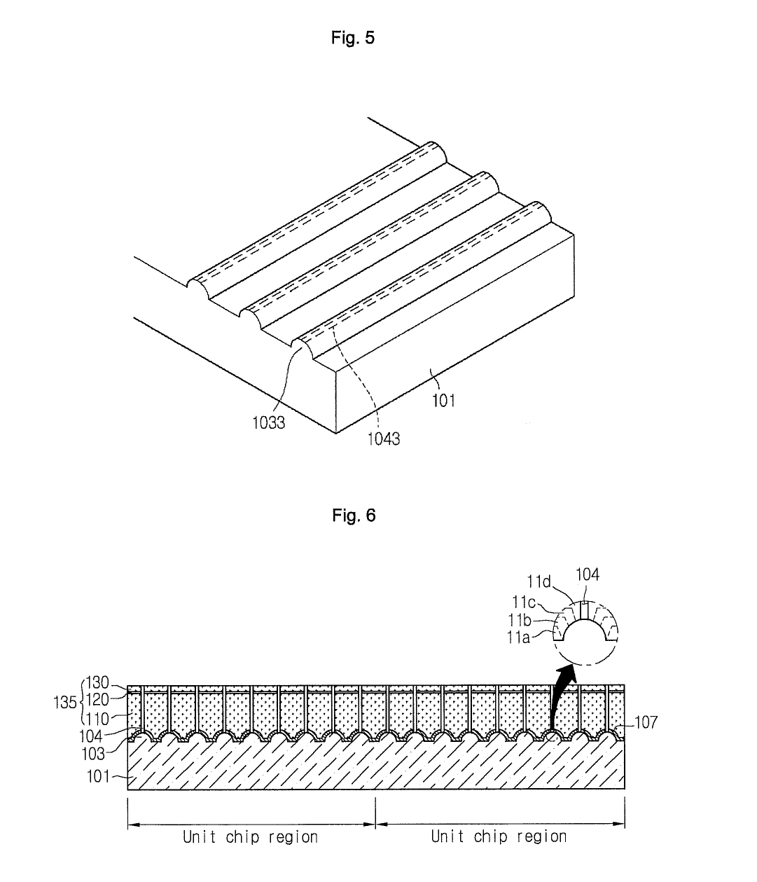

Further, as shown in FIG. 5, convex parts 1033 may have the stripe shapes extending in one direction and holes 1043 may have the stripe shapes extending in one direction. In this case, the holes 1043 may serve as walls, so the a region where the semiconductor layers constituting the buffer layer 107 and the light emitting structure 135 are formed may be distinguished from a region where the holes 1043 are formed. In this case, the light may not travel in the horizontal direction, but travel in the vertical direction due to the difference in the refractive index, so that the light extraction efficiency can be improved.

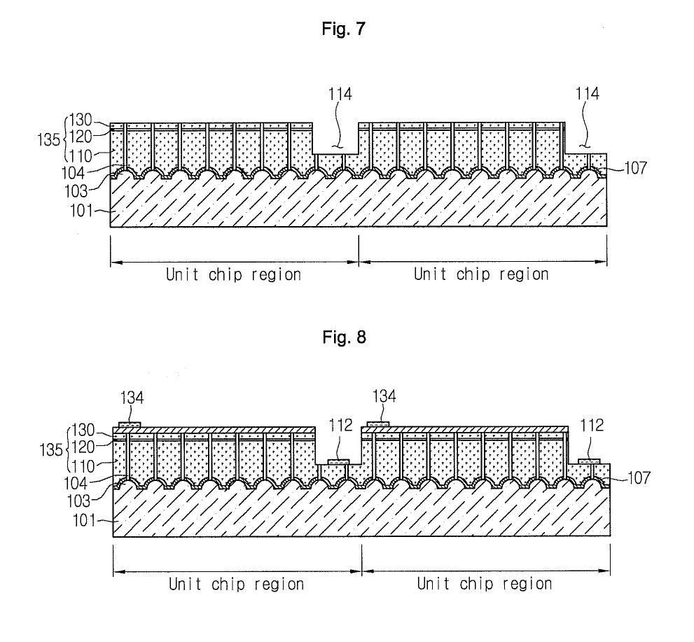

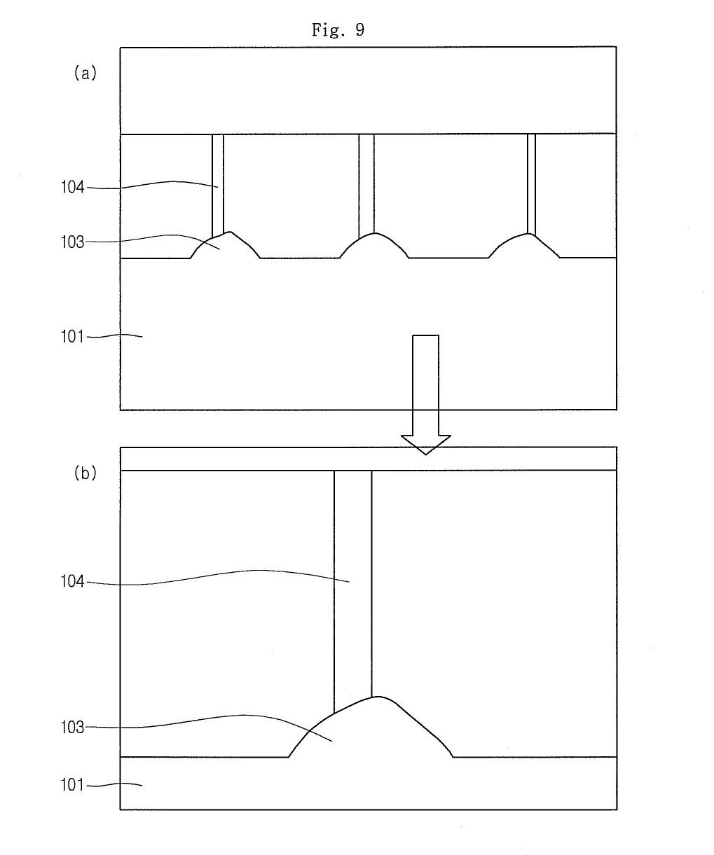

Hereinafter, the method of fabricating the light emitting device according to the embodiment will be described with reference to FIGS. 6 to 8. FIGS. 6 to 8 are sectional views showing the procedure for fabricating the light emitting device shown in FIG. 1. For the purpose of simplicity and clarity, description about the elements and structures that have been described above will be omitted and the following description will be focused on the different parts.

As shown in FIG. 6, the buffer layer 107 and the light emitting structure 135 are formed on the substrate 101.

The buffer layer 107 and the light emitting structure 135 can be formed by sequentially growing semiconductor layers corresponding to the buffer layer 107, the first conductive semiconductor layer 110, the active layer 120 and the second conductive semiconductor layer 130 on the substrate 101.

For instance, the buffer layer 107 and the light emitting structure 135 can be formed through the metal organic chemical vapor deposition (MOCVD), chemical vapor deposition (CVD), plasma-enhanced chemical vapor deposition (PECVD), molecular beam epitaxy (MBE), or hydride vapor phase epitaxy (HVPE), but the embodiment is not limited thereto. The semiconductor layers (that is, the buffer layer 107 and the light emitting structure 135) having the holes 104 can be formed as follows.

When the semiconductor layers are grown on the substrate 101, the semiconductor layers are grown on the planar section between convex parts 103 (see, reference numeral 11a of FIG. 6). When the semiconductor layers are grown at the peripheral portion of the convex parts 103, the semiconductor layers are subject to the vertical growth more than the lateral growth (see, reference numerals 11b, 11c and 11d of FIG. 6). Thus, when the semiconductor layers are grown at the peripheral portion of the convex parts 103, the holes 104 remain at the center portions of the convex parts 103.

For instance, if the temperature and/or pressure is increased, the semiconductor layers are subject to the lateral growth more that the vertical growth. In contrast, if the temperature and/or pressure is reduced, the semiconductor layers are subject to the vertical growth more that the lateral growth. Thus, after growing the semiconductor layers on the planar section between the convex parts 103 at the low growth rate to the extent that the semiconductor layers may not grow to the upper portions of the convex parts 103, the vertical growth can be induced by reducing the temperature and/or pressure. Thus, the semiconductor layers can be grown in a state that the holes 104 are formed at the center portions of the convex parts 103.

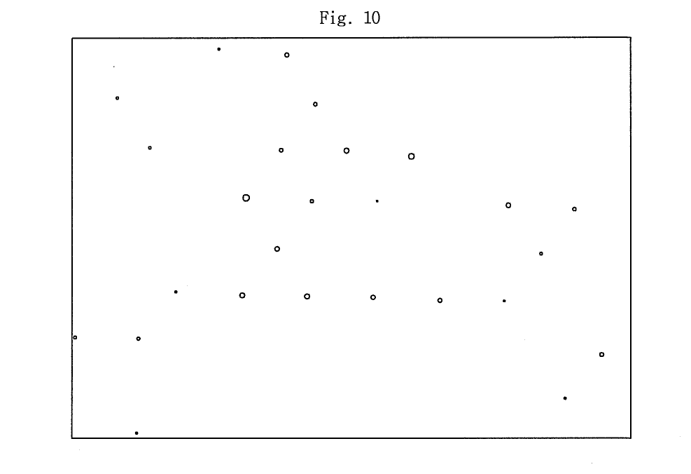

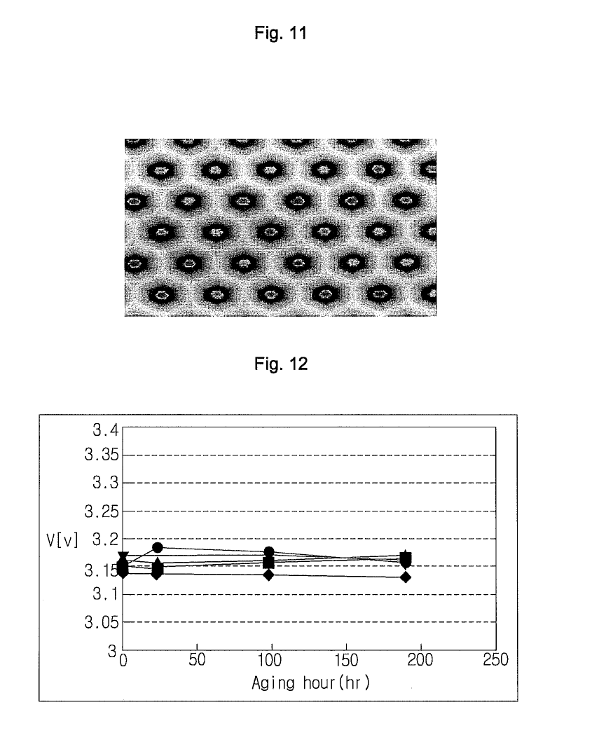

FIG. 9 is a photographic view showing a section of the semiconductor layer which is grown to have the holes 103 corresponding to the convex parts 104 of the substrate 101, and FIG. 10 is a photographic view showing a top surface of the semiconductor layer. FIG. 11 is a photographic view showing a top surface of the buffer layer 107 which is grown to have holes corresponding to convex parts of the substrate. Referring to FIG. 9, the semiconductor layers constituting the buffer layer 107 and the light emitting structure 135 have been grown in a state that the holes 104 are formed corresponding to the convex parts 103. Referring to FIG. 10, the holes 104 are formed up to the top surface of the light emitting structure 135. Referring to FIGS. 10 and 11, the holes 104 schematically have the circular shapes or hexagonal shapes.

Then, as shown in FIG. 3, a mesa etching is performed to partially remove the second conductive semiconductor layer 130, the active layer 120 and the first conductive semiconductor layer 110, thereby forming an opening 114. The first conductive semiconductor layer 110 is partially exposed through the opening 114. The mesa etching may include a dry etching.

After that, as shown in FIG. 4, the transmissive conductive layer 132 and the second electrode 134 are formed on the second conductive semiconductor layer 130, and the first electrode 112 is formed on the first conductive semiconductor layer 110 exposed through the opening. The transmissive conductive layer 132, the second electrode 134 and the first electrode 112 can be formed through the sputtering or deposition process.

According to the present embodiment, the transmissive conductive layer 132, the second electrode 134 and the first electrode 112 are formed after the mesa etching has been performed. However, this process can be variously modified within the scope of the embodiment.

Then, the light emitting device including a plurality of unit chip areas is divided into individual chips through a chip isolation process, so that a plurality of light emitting devices 100 shown in FIG. 1 can be fabricated.

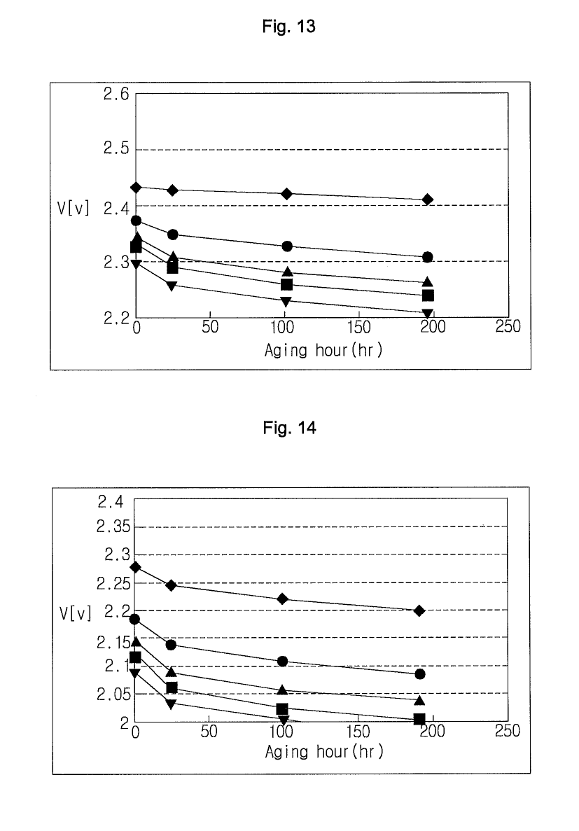

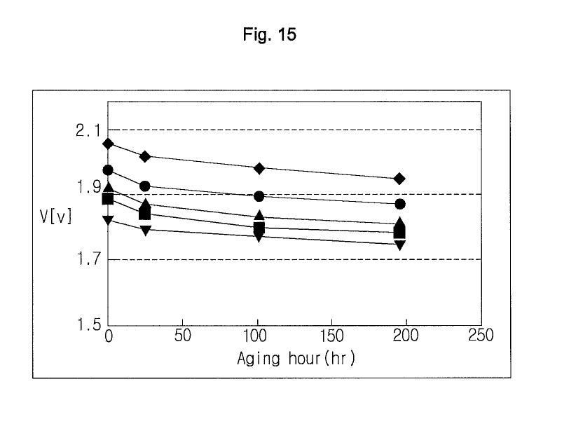

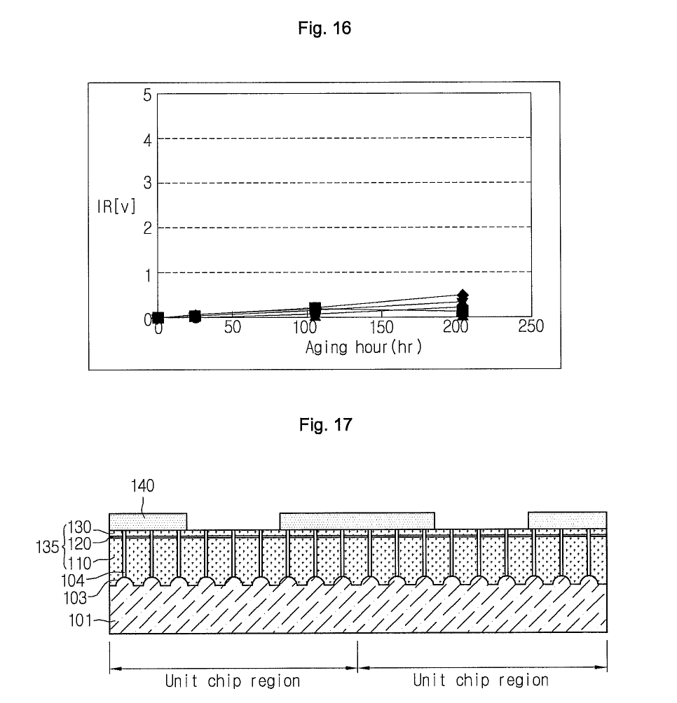

FIGS. 12 to 15 show voltages, which are measured by aging five light emitting devices 100 fabricated through the above process using currents of 80 mA, 10 μA, 1 μA, and 0.1 μA. In addition, FIG. 16 shows a voltage, which is measured by aging the five light emitting devices according to manufacture examples using a voltage of −5V.

Referring to FIGS. 12 to 15, the light emitting device 100 according to the manufacture example may not represent significant variation during the aging time under the high current of 80 mA and the low current. It is generally known in the art that the low-current characteristic is degraded due to the loss caused by the defect in the semiconductor layer. However, the light emitting device 100 according to the manufacture example represents the superior characteristic under the low current condition. This is because the defect may not occur at the upper portions of the convex parts 103 due to the holes 104. In addition, referring to FIG. 16, when −5V is applied, the light emitting device 100 according to the manufacture example represents low leakage current. Thus, it can be understood that the light emitting device 100 according to the manufacture example represents the superior reliability.

Hereinafter, a light emitting device and a method of fabricating the light emitting device according to another embodiment will be described in detail with reference to FIGS. 17 to 24. FIGS. 17 to 24 are sectional views showing the procedure for fabricating the light emitting device according to another embodiment.

For the purpose of simplicity and clarity, description about the elements and structures that have been described above will be omitted and the following description will be focused on the different parts.

The light emitting device according to another embodiment is different from the light emitting device shown in FIG. 1 in that light emitting device according to another embodiment is a vertical light emitting device in which the substrate 101 (see, FIG. 1) is removed and a conductive support substrate 175 is used as a second electrode.

As shown in FIG. 17, a buffer layer (not shown) and the light emitting structure 135 are formed on the substrate 101 serving as the growth substrate. Then, a protective member 140 is selectively formed on the light emitting structure 135 corresponding to the unit chip area. The protective member 140 can be formed around the unit chip area by using a patterned mask. The protective member 140 can be formed through various deposition schemes, such as E-beam evaporation, sputtering or PECVD.

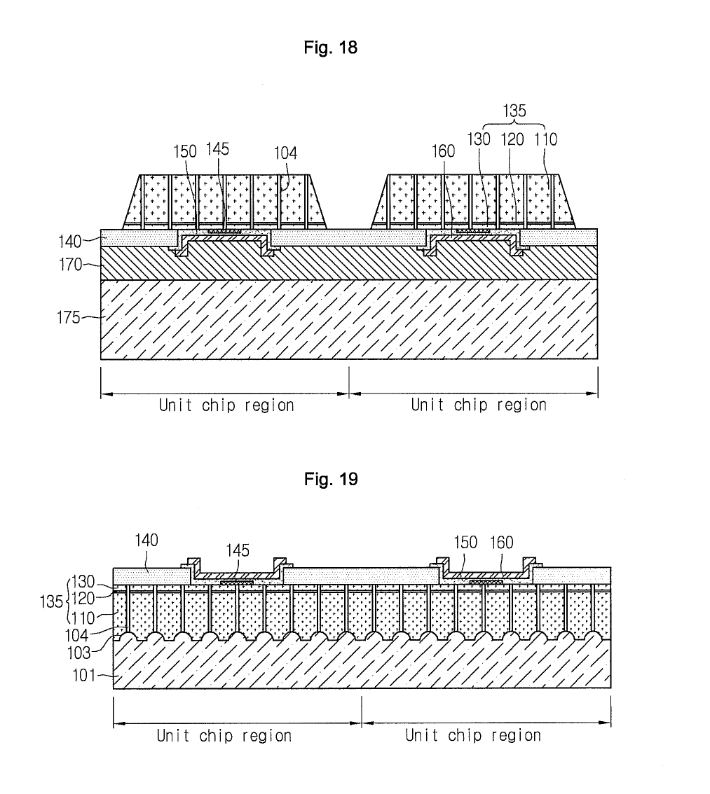

Then, as shown in FIG. 18, a current blocking layer 145 is formed on the second conductive semiconductor layer 130. The current blocking layer 145 can be formed by using a mask pattern.

Although FIGS. 17 and 18 show the protective member 140 and the current blocking layer 145, which are formed through separate processes, it is also possible to simultaneously form the protective member 140 and the current blocking layer 145 by using the same material through one process. For instance, after forming a SiO₂ layer on the second conductive semiconductor layer 130, the protective member 140 and the current blocking layer 145 can be simultaneously formed by using the mask pattern.

After that, as shown in FIG. 19, an ohmic layer 150 and a reflective layer 160 are sequentially formed on the second conductive semiconductor layer 130 and the current blocking layer 145.

For instance, the ohmic layer 150 and the reflective layer 160 can be formed through one of E-beam evaporation, sputtering and PECVD.

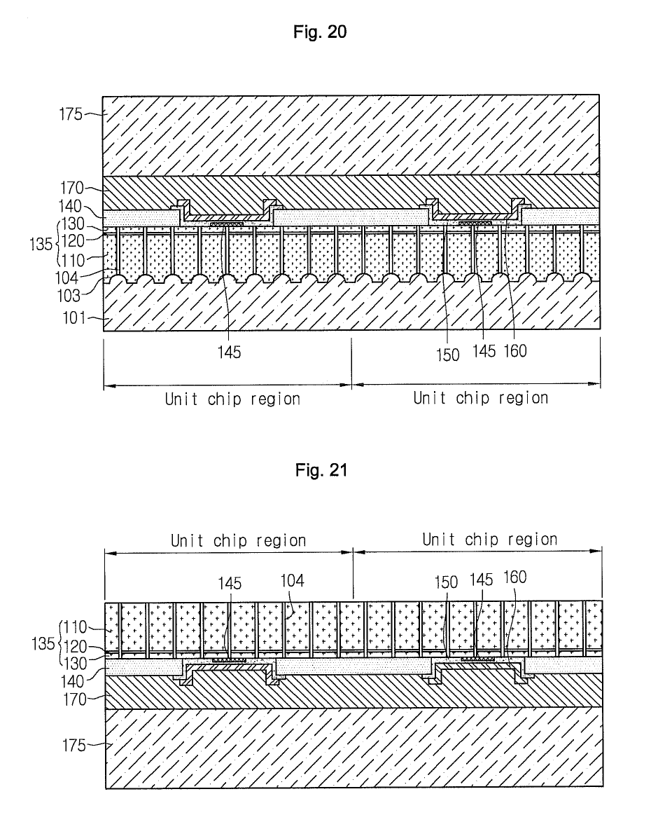

Then, as shown in FIG. 20, the conductive support substrate 175 is bonded to the structure shown in FIG. 19 by using a bonding layer 170. The bonding layer 170 is bonded to the reflective layer 160, an end of the ohmic layer 150 and the protective member 140 to reinforce the bonding strength among them.

Then, as shown in FIG. 21, the substrate 101 is removed from the light emitting structure 135. FIG. 21 shows an inverse structure of FIG. 20.

The substrate 101 may be removed through a laser lift off scheme or a chemical lift off scheme. In order to completely remove the substrate 101, the buffer layer (not shown) interposed between the convex parts 103 can be removed together with the light emitting structure 135.

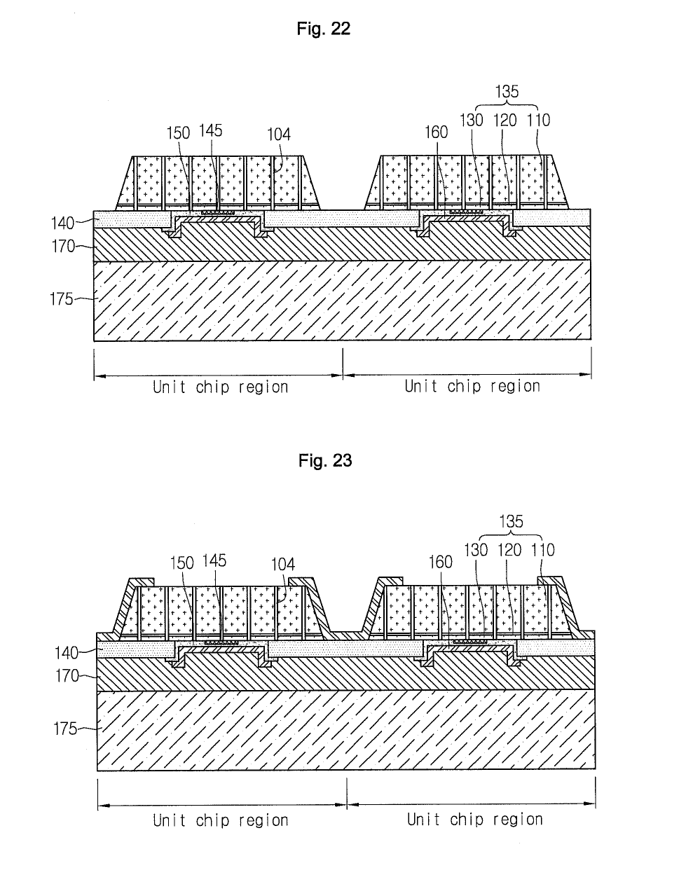

Then, as shown in FIG. 22, the light emitting structure 135 is divided into a plurality of light emitting structure layers through an isolation etching process along a unit chip area. For example, the isolation etching process may include a dry etching scheme such as an ICP (Inductively Coupled Plasma) etching scheme.

Referring to FIG. 23, after forming a passivation layer 180 on the protective member 140 and the light emitting structure 135, the passivation layer 180 may be selectively removed to expose the top surface of the first conductive semiconductor layer 110.

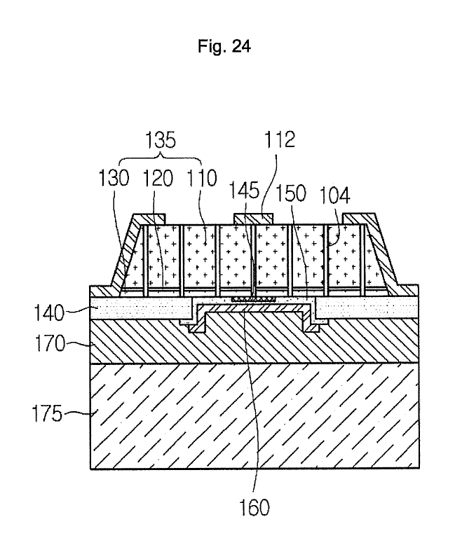

Then, as shown in FIG. 24, the first electrode 112 is formed on the light emitting device and the structure is divided into unit chip areas through a chip isolation process, so that a plurality of light emitting devices shown in FIG. 24 can be fabricated.

The conductive support substrate 175 supports the light emitting structure 135 and supplies power to the light emitting structure 135 together with the first electrode 112. The conductive support substrate 175 may include conductive materials or semiconductor materials. For instance, the conductive support substrate 175 may include at least one of Cu, Au, Ni, Mo, Cu—W and a carrier wafer (for instance: Si, Ge, GaAs, ZnO, SiC, SiGe, GaN, or Ga2O3).

The bonding layer 170 is formed on the conductive support substrate 175. The bonding layer 170 is an adhesive layer formed under the reflective layer 160 and the protective member 140. The bonding layer 170 makes contact with the reflective layer 160, the end of the ohmic layer 150 and the protective member 140 to reinforce the bonding strength among them.

The bonding layer 170 may include a barrier metal or a bonding metal. For instance, the bonding layer 170 may include at least one of Ti, Au, Sn, Ni, Cr, Ga, In, Bi, Cu, Al, Si, Ag, Ta and an alloy thereof.

The reflective layer 160 may be formed on the bonding layer 170. The reflective layer 160 reflects the light, which is generated from the light emitting structure 135 and traveled toward the reflective layer 160, to improve the light emitting efficiency of the light emitting device.

For instance, the reflective layer 160 may include at least one of Ag, Ni, Al, Rh, Pd, Ir, Ru, Mg, Zn, Pt, Au, Hf and an alloy thereof. In addition, the reflective layer 160 can be prepared as a multiple layer by using the above metal or alloy and a transmissive conductive material, such as ITO, IZO, IZTO, IAZO, IGTO, IGZO, AZO, ATO, or GZO. For instance, the reflective layer 160 may have the stack structure including IZO/Ni, AZO/Ag, IZO/Ag/Ni, AZO/Ag/Ni, Ag/Cu, or Ag/Pd/Cu. The ohmic layer 150 is formed on the reflective layer 160. The ohmic layer 150 makes ohmic-contact with the second conductive semiconductor layer 130 to readily supply power to the light emitting structure 135. The ohmic layer 150 can be prepared as a single layer or a multiple layer by using at least one of ITO, IZO, IZTO, IAZO, IGZO, IGTO, AZO, ATO, GZO (gallium zinc oxide), IrOx, RuOx, RuOx/ITO, In, Zn, Sn, Ni, Ag, Pt, Ni/IrOx/Au, and Ni/IrOx/Au/ITO.

According to the embodiment, the top surface of the reflective layer 160 makes contact with the ohmic layer 150. However, it is also possible to allow the reflective layer 160 to make contact with the protective member 140, the current blocking layer 145 or the light emitting structure 135.

The current blocking layer 145 may be disposed between the ohmic layer 150 and the second conductive semiconductor layer 130. The top surface of the current blocking layer 145 makes contact with the second conductive semiconductor layer 130, and the bottom surface and lateral sides of the current blocking layer 145 make contact with the ohmic layer 150.

At least a part of the current blocking layer 145 is overlapped with the first electrode 112 in the vertical direction. Thus, the concentration of a current onto the shortest path between the first electrode 112 and the conductive support substrate 175 can be reduced, so that the light emission efficiency of the light emitting device 100 can be improved.

The current blocking layer 145 may include a material having an electric insulating property, a material having electrical conductivity lower than that of a material constituting the reflective layer 160 or the bonding layer 170, or a material forming schottky contact with respect to the second conductive semiconductor layer 130. For example, the current blocking layer 145 may include at least one selected from the group consisting of ITO, IZO, IZTO, IAZO, IGZO, IGTO, AZO, ATO, ZnO, SiO2, SiOx, SiOxNy, Si3N4, Al2O3, TiOx, TiO2, Ti, Al and Cr.

Although it has been described that the ohmic layer 150 makes contact with the bottom surface and lateral sides of the current blocking layer 145, the embodiment is not limited thereto. For instance, the ohmic layer 150 may be spaced apart from the current blocking layer 145 or only makes contact with the lateral sides of the current blocking layer 145. In addition, the current blocking layer 145 can be disposed between the reflective layer 160 and the ohmic layer 150. The protective member 140 may be formed on the outer peripheral portion of the top surface of the bonding layer 170. That is, the protective member 140 may be formed at the outer peripheral portion between the light emitting structure 135 and the bonding layer 170. Thus, the protective member 140 may have a ring shape, a loop shape or a frame shape. A part of the protective member 140 may overlap with the light emitting structure 135 in the vertical direction.

The protective member 140 may lengthen the distance between the bonding layer 170 and the active layer 120, thereby preventing the electric short from occurring between the bonding layer 170 and the active layer 120. In addition, protective member 140 may prevent moisture from penetrating into a gap between the light emitting structure 135 and the conductive support substrate 175.

Further, the protective member 140 may prevent the electric short during the chip isolation process. In more detail, when the isolation etching is performed to divide the light emitting structure 135 into unit chip areas, fragments generated from the bonding layer 170 may be attached between the second conductive semiconductor layer 130 and the active layer 120 or between the active layer and the first conductive semiconductor layer 110. In this case, the electric short may occur. In this regard, the protective member 140 is formed by using an insulating material, which may not be broken or slightly broken or may not generate or slightly generate fragments during the isolation etching, in order to prevent the electric short.

The protective member 140 may include a material having an electric insulating property, a material having electrical conductivity lower than that of a material constituting the reflective layer 160 or the bonding layer 170, or a material forming schottky contact with respect to the second conductive semiconductor layer 130.

However, the embodiment is not limited to the above. For instance, the protective member 140 may be formed by using a metal within the scope of the embodiment.

In detail, the protective member 140 may include at least one of ITO, IZO, IZTO, IAZO, IGZO, IGTO, AZO, ATO, ZnO, SiO₂, SiOx, SiOxNy, Si₃N₄, Al₂O₃, TiOx, TiO₂, Ti, Al and Cr.

The light emitting structure 135 may be formed on the ohmic layer 150 and the protective member 140. The lateral side of the light emitting structure 135 may be inclined through the isolation etching, which is performed to divide the light emitting structure 135 into the unit chip areas.

The second conductive semiconductor layer 130 may be formed on the ohmic layer 150 and the protective member 140, the active layer 120 may be formed on the second conductive semiconductor layer 130, and the first conductive semiconductor layer 110 may be formed on the active layer 120.

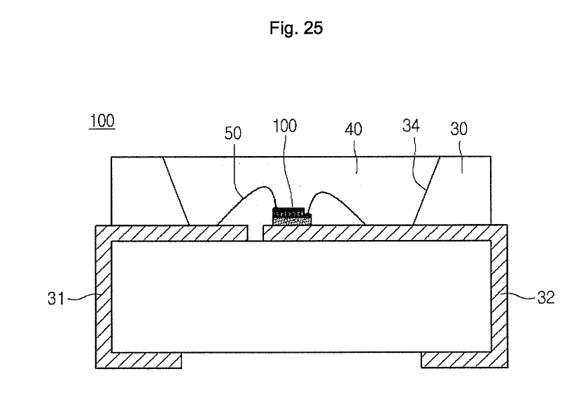

Hereinafter, a light emitting device package including the light emitting device according to the embodiment will be described with reference to FIG. 25. FIG. 25 is a sectional view showing the light emitting device package including the light emitting device according to the embodiment.

Referring to FIG. 25, the light emitting device package according to the embodiment includes a package body 30, first and second lead frames 31 and 32 formed on the package body 30, a light emitting device 100 provided on the package body 30 and electrically connected to the first and second lead frames 31 and 32 and a molding member 40 that surrounds the light emitting device 100.

The package body 30 may include resin such as PPA (polyphthal amide), LCP (liquid crystal polymer), PA9T (polyamide9T), metal, photosensitive glass, sapphire (Al₂O₃), or a ceramic substrate (PCB), but the embodiment is not limited thereto.

The cavity body 30 is formed with a cavity 34 having an open top surface. Lateral sides of the cavity 34 may be inclined or vertical to a bottom surface of the cavity 34.

The first and second lead frames 31 and 32 electrically connected to the light emitting device 100 are installed on the package body 30. The first and second lead frames 31 and 32 may include a metal plate having a predetermined thickness and another metal layer may be coated on the first and second lead frames 31 and 32. The first and second lead frames 31 and 32 may include metals having superior conductivity, such as Ti, Cu, Ni, Au, Cr, Ta, Pt, Sn, or Ag.

The first and second lead frames 31 and 32 supply power to the light emitting device 100. The first and second lead frames 31 and 32 reflect the light emitted from the light emitting device 100 to improve the light efficiency. Further, the first and second lead frames 31 and 32 may dissipate heat generated from the light emitting device 100 to the outside.

The light emitting device 100, which is electrically connected to the first and second lead frames 31 and 32, is installed in the cavity 34. The light emitting device 100 can be electrically connected to the first and second lead frames 31 and 32 through one of a wire scheme, a flip chip scheme and a die bonding scheme. According to the embodiment, the light emitting device 100 is electrically connected to the first lead frame 31 through a wire 50 and directly makes contact with the second lead frame 32.

According to the present embodiment, the light emitting device 100 is positioned in the cavity 34 of the package body 30, but the embodiment is not limited thereto. For instance, the package body 30 may have no cavity 34 and the light emitting device 100 can be installed on the package body 30.

The molding member 40 surrounds the light emitting device 100 to protect the light emitting device 100. In addition, the molding member 40 may include a phosphor to change the wavelength of the light emitted from the light emitting device 100.

However, the embodiment is not limited to the above. For instance, the phosphor may be provided in a coating layer formed on the molding member 40 or in a coating layer surrounding the light emitting device. In addition, the phosphor may be positioned in a lens (not shown) formed on the molding member.

The phosphor may include a garnet phosphor, a silicate phosphor or an oxynitride phosphor. A single phosphor may be used or a plurality of phosphors may be mixed in use.

Although the light emitting device shown in FIG. 1 is illustrated and described in the drawings and description, the embodiment is not limited thereto. For instance, the light emitting device shown in FIGS. 6 to 8 and FIGS. 18 to 24 may also be employed.

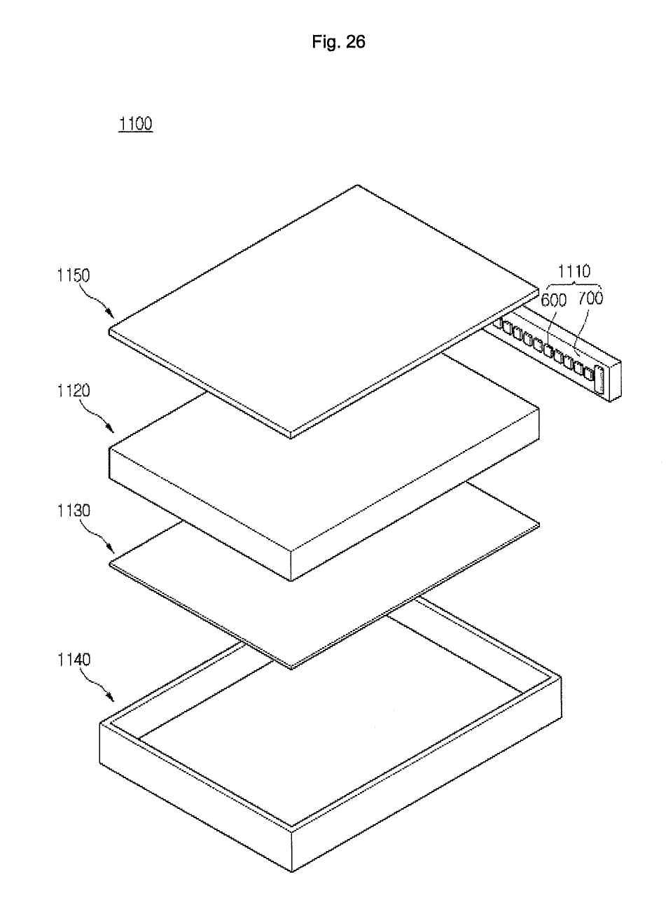

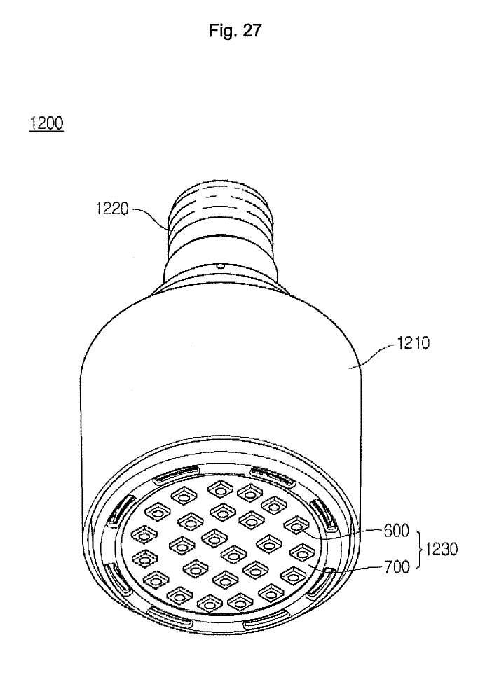

The light emitting device package according to the embodiment may serve as a lighting system, such as a backlight unit, an indicator, a lamp or a street lamp. Hereinafter, the lighting system will be described with reference to FIGS. 26 and 27. FIG. 26 is an exploded perspective view showing a backlight unit 1100 including the light emitting device package according to the embodiment. The backlight unit 1100 shown in FIG. 26 is an example of a lighting system and the embodiment is not limited thereto.

Referring to FIG. 26, the backlight unit 1100 may include a bottom cover 1140, a light guide member 1120 provided in the bottom cover 1140, and a light emitting module 1110 installed on at least one side or the bottom surface of the light guide member 1120. In addition, a reflective sheet 1130 may be disposed under the light guide member 1120.

The bottom cover 1140 has a box shape having an open top surface to receive the light guide member 1120, the light emitting module 1110 and the reflective sheet 1130 therein. In addition, the bottom cover 1140 may include metallic material or resin material, but the embodiment is not limited thereto.

The light emitting module 1110 may include a plurality of light emitting device packages 600 mounted on a substrate 700. The light emitting device packages 600 can supply light to the light guide member 1120.

As shown in FIG. 26, the light emitting module 1110 is installed on at least one inner side of the bottom cover 1140 to provide the light to at least one side of the light guide member 1120.

In addition, the light emitting module 1110 can be provided under the light guide member 1120 in the bottom cover 1140 to provide the light toward the bottom surface of the light guide member 1120. Such an arrangement can be variously changed according to the design of the backlight unit 1100.

The light guide member 1120 is installed in the bottom cover 1140. The light guide member 1120 converts the light emitted from the light emitting module 1110 into the surface light to guide the surface light toward the display panel (not shown).

The light guide member 1120 may include a light guide plate. For instance, the light guide plate can be manufactured by using acryl-based resin, such as PMMA (polymethyl methacrylate), PET (polyethylene terephthalate), COC, PC (polycarbonate) or PEN (polyethylene naphthalate) resin.

An optical sheet 1150 may be provided over the light guide member 1120.

The optical sheet 1150 may include at least one of a diffusion sheet, a light collection sheet, a brightness enhanced sheet, and a fluorescent sheet. For instance, the optical sheet 1150 has a stack structure of the diffusion sheet, the light collection sheet, the brightness enhanced sheet, and the fluorescent sheet. In this case, the diffusion sheet 1150 uniformly diffuses the light emitted from the light emitting module 1110 such that the diffused light can be concentrated onto the display panel (not shown) by the light collection sheet. The light output from the light collection sheet is randomly polarized and the brightness enhanced sheet increases the degree of polarization of the light output from the light collection sheet. The light collection sheet may include a horizontal and/or vertical prism sheet. In addition, the brightness enhanced sheet may include a dual brightness enhancement film and the fluorescent sheet may include a transmittive plate or a transmittive film including a phosphor.

The reflective sheet 1130 can be disposed under the light guide member 1120. The reflective sheet 1130 reflects the light, which is emitted through the bottom surface of the light guide member 1120, toward the light exit surface of the light guide member 1120. The reflective sheet 1130 may include a resin material having a high reflectance, such as PET, PC, polyvinyl chloride or resin, but the embodiment is not limited thereto.

FIG. 27 is a perspective view showing a lighting unit 1200 including the light emitting device package according to the embodiment. The lighting unit 1200 shown in FIG. 27 is only one example and the embodiment is not limited thereto.

Referring to FIG. 27, the lighting unit 1200 includes a case body 1210, a light emitting module 1230 installed in the case body 1210, and a connection terminal 1220 installed in the case body 1210 to receive power from an external power source.

Preferably, the case body 1210 includes a material having superior heat dissipation property. For instance, the case body 1210 includes a metallic material or a resin material.

The light emitting module 1230 may include the substrate 700 and at least one light emitting device package 600 installed on the substrate 700.

The substrate 700 includes an insulating member printed with a circuit pattern. For instance, the substrate 700 includes a PCB (printed circuit board), an MC (metal core) PCB, a flexible PCB, or a ceramic PCB.

In addition, the substrate 700 may include a material that effectively reflects the light. The surface of the substrate 700 can be coated with a color, such as a white color or a silver color, to effectively reflect the light.

At least one light emitting device package 600 can be installed on the substrate 700. Each light emitting device package 600 may include at least one light emitting diode (LED). The LED may include a colored LED that emits the light having the color of red, green, blue or white and a UV (ultraviolet) LED that emits UV light.

The light emitting module 1230 can be variously combined to provide various colors and brightness. For instance, the white LED, the red LED and the green LED can be combined to achieve the high color rendering index (CRI). In addition, a fluorescent sheet can be provided in the path of the light emitted from the light emitting module 1230 to change the wavelength of the light emitted from the light emitting module 1230. For instance, if the light emitted from the light emitting module 1230 has a wavelength band of blue light, the fluorescent sheet may include a yellow phosphor. In this case, the light emitted from the light emitting module 1230 passes through the fluorescent sheet so that the light is viewed as white light.

The connection terminal 1220 is electrically connected to the light emitting module 1230 to supply power to the light emitting module 1230. Referring to FIG. 27, the connection terminal 1220 has a shape of a socket screw-coupled with the external power source, but the embodiment is not limited thereto. For instance, the connection terminal 1220 can be prepared in the form of a pin inserted into the external power source or can be connected to the external power source through a wire.

According to the lighting system as described above, at least one of the light guide member, the diffusion sheet, the light collection sheet, the brightness enhanced sheet and the fluorescent sheet is provided in the path of the light emitted from the light emitting module, so that the desired optical effect can be achieved.

As described above, the lighting system includes the light emitting device package having the superior reliability, so that the reliability can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a substrate having first and second surfaces opposite to each other and formed on the first surface thereof with a plurality of convex parts; and
a light emitting structure disposed on the first surface of the substrate and including a first conductive semiconductor layer, a second conductive semiconductor layer, and an active layer between the first and second conductive semiconductor layers,
wherein the light emitting structure has holes corresponding to the convex parts of the substrate.

2. The light emitting device of claim 1, wherein each hole is disposed on a center of each convex part when viewed in a plan view.

3. The light emitting device of claim 1, wherein each hole extends to a top surface of the light emitting structure from each convex part.

4. The light emitting device of claim 1, wherein a lateral side of each hole is inclined at an angle of 80° to 100° with respect to the second surface.

5. The light emitting device of claim 1, wherein each hole has a circular shape or a hexagonal shape when viewed in a plan view.

6. The light emitting device of claim 1, wherein the holes correspond to the convex parts in one-to-one correspondence.

7. The light emitting device of claim 1, wherein each convex part has a circular sectional shape or a polygonal sectional shape.

8. The light emitting device of claim 1, wherein a concave part is disposed on an upper portion of each convex part and each hole is disposed on each concave part.

9. The light emitting device of claim 1, wherein the substrate includes sapphire.

10. The light emitting device of claim 1, wherein an area of each hole is 5% to 50% based on an area of each convex part.

11. The light emitting device of claim 10, wherein the area of each hole is 10% to 30% based on the area of each convex part.

12. The light emitting device of claim 1, wherein each hole has a width of at least 0.1 μm.

13. The light emitting device of claim 1, wherein the convex parts are has a stripe shape.

14. The light emitting device of claim 13, wherein the holes has a stripe shape.

15. A light emitting device comprising:
a conductive substrate having first and second surfaces opposite to each other; and
a light emitting structure disposed on the first surface of the substrate and including a first conductive semiconductor layer, a second conductive semiconductor layer, and an active layer between the first and second conductive semiconductor layers,
wherein the light emitting structure has holes through the light emitting structure.

16. The light emitting device of claim 15, a lateral side of each hole is inclined at an angle of 80° to 100° with respect to the second surface.

17. The light emitting device of claim 15, wherein each hole has a circular shape or a hexagonal shape when viewed in a plan view.

18. The light emitting device of claim 15, wherein each hole has a width of at least 0.1 μm.

19. The light emitting device of claim 15, wherein the holes are arranged in a stripe shape.

20. The light emitting device of claim 15, further comprising:
a reflective layer between the conductive substrate and the light emitting structure; and
a current blocking layer on the reflective layer.
